(19) United States
(12) Patent Application Publication
(10) Pub. No.: US 2017/0112026 A1
(43) Pub. Date: Apr. 20, 2017

(54) ELECTROMAGNETIC WAVE SHIELDING SHEET AND METHOD FOR MANUFACTURING SAME

(71) Applicant: LG Hausys, Ltd., Seoul (KR)

(72) Inventors: Da-Young YU, Anyang-si, Gyeonggi-do (KR); Hwan-Seok PARK, Anyang-si, Gyeonggi-do (KR); Hae-Rim NAM, Seoul (KR); Seong-Hoon YUE, Seongnam-si, Gyeonggi-do (KR); Hea-Won KWON, Seoul (KR); Yea-Ri SONG, Seoul (KR); Yu-Jun KIM, Anyang-si, Gyeonggi-do (KR)

(73) Assignee: LG HAUSYS, Ltd., Seoul (KR)

(21) Appl. No.: 15/128,428

(22) PCT Filed: Feb. 26, 2015
(86) PCT No.: PCT/KR2015/001879

§ 371 Date: Sep. 23, 2016

(30) Foreign Application Priority Data
Mar. 25, 2014 (KR) 10-2014-0034437

(51) Int. Cl. H05K 9/00; C09K 5/14

(52) U.S. Cl. CPC H05K 9/0081; C09K 5/14; B29C 43/203

(57) ABSTRACT

Provided are an electromagnetic wave shielding sheet and a method for producing the same, the electromagnetic wave shielding sheet comprising a unit structure, which comprises a heat-radiating layer and a magnetic layer, and comprising a stack structure in which a plurality of the unit structures is stacked, wherein the sum of total thickness of the heat-radiating layers has a ratio of 0.1 to 0.7 with regard to the total thickness of the electromagnetic wave shielding sheet.

### TECHNICAL FIELD

The present invention relates to an electromagnetic wave shielding sheet and a method for producing the same.

### BACKGROUND ART

An electromagnetic wave shielding sheet may be included in portable terminals, etc. The electromagnetic wave shielding sheet basically needs to have a high magnetic permeability. In recent years, wireless charging, rapid charging, and high-capacity charging have been increasingly demanded in charging the portable terminals, etc., and accordingly, importance of a heat-radiation function for effectively removing heat that occurs during the charging is on the rise.

### DISCLOSURE

### Technical Problem

It is an aspect of the present invention to provide an electromagnetic wave shielding sheet capable of implementing excellent heat-radiation property while having high permeability.

It is another aspect of the present invention to provide a method for producing the electromagnetic wave shielding sheet.

### Technical Solution

In accordance with one aspect of the present invention, an electromagnetic wave shielding sheet includes: a stack structure of a plurality of unit structures, each of the unit structures including a heat-radiating layer and a magnetic layer, wherein the sum of total thickness of the heat-radiating layers has a ratio of 0.1 to 0.7 with regard to the total thickness of the electromagnetic wave shielding sheet.

The stack structure may include the magnetic layer as a top layer or a bottom layer.

The total thickness of the electromagnetic wave shielding sheet may be about 200 μm to about 500 μm.

The heat-radiating layer may include inorganic particles and an organic binder.

The heat-radiating layer may include about 80 wt % to about 99 wt % of the inorganic particles and about 1 wt % to about 20 wt % of the organic binder.

The inorganic particle may include at least one selected from the group consisting of graphite, graphene, carbon nanotube (CNT), boron nitride (BN), aluminum nitride (AlN), and combinations thereof.

The organic binder may include at least one selected from the group consisting of a styrene-butadiene rubber (SBR), a styrene-ethylene-butylene-styrene copolymer (SEBS), an ethylene-vinyl acetate copolymer (EVA), low density polyethylene (LDPE), an acrylic resin, an ester-based resin, an epoxy resin, and combinations thereof.

The magnetic layer and the heat-radiating layer may include the same organic binder.

In accordance with another aspect of the present invention, a method for producing an electromagnetic wave shielding sheet includes: preparing a magnetic layer; forming a unit structure by stacking a heat-radiating layer on one surface of the magnetic layer; forming a stack structure in which the magnetic layers and the heat-radiating layers are alternately stacked with each other by stacking the at least two unit structures; and forming the electromagnetic wave shielding sheet by thermocompressing the stack structure, wherein the sum of total thickness of the heat-radiating layers has a ratio of 0.1 to 0.7 with regard to the total thickness of the electromagnetic wave shielding sheet.

The forming of the unit structure may include: preparing a coating liquid by mixing an organic solvent with a solid containing inorganic particles and an organic binder; and stacking the heat-radiating layer by coating the coating liquid on one surface of the magnetic layer.

The forming of the stack structure may include forming the magnetic layer as a top layer or a bottom layer of the stack structure.

### Advantageous Effects

The electromagnetic wave shielding sheet may have high charging efficiency and implement heat-radiation property for effectively removing heat, that is, a property in which thermal conductivity is high.

In addition, the electromagnetic wave shielding sheet both of which permeability and heat-radiation property are excellent may be manufactured by the method for producing the electromagnetic wave shielding sheet.

### DESCRIPTION OF DRAWINGS

FIG. 1 is a cross-sectional view schematically showing an electromagnetic wave shielding sheet according to an exemplary embodiment of the present invention.

FIG. 2 is a cross-sectional view schematically showing an electromagnetic wave shielding sheet according to another exemplary embodiment of the present invention.

FIG. 3 is a cross-sectional view schematically showing an electromagnetic wave shielding sheet according to still another exemplary embodiment of the present invention.

### BEST MODE

Hereinafter, various advantages and features of the present invention and methods accomplishing thereof will become apparent with reference to the following description of embodiments. However, the present invention is not limited to embodiments disclosed herein but will be implemented in various forms. These embodiments are provided by way of example only so that a person of ordinary skilled in the art can fully understand the disclosures of the present invention and the scope of the present invention. Therefore, the present invention will be defined only by the scope of the appended claims. Like reference numerals refer to like components throughout the specification.

In the drawings, thicknesses of various layers and regions are exaggerated for clarity. In the drawings, thicknesses of partial layers and regions are exaggerated for convenience of explanation. It will be understood that when an element such as a layer, film, region, or substrate is referred to as being “on” another element, it can be directly on the other element or intervening elements may also be present. On the other hand, disposing any parts just on another part means no other parts therebetween.

Electromagnetic Wave Shielding Sheet

An embodiment of the present invention is directed to providing an electromagnetic wave shielding sheet including: a stack structure of a plurality of unit structures, each of the unit structures including a heat-radiating layer and a magnetic layer, wherein the sum of total thickness of the heat-radiating layers has a ratio of 0.1 to 0.7 with regard to the total thickness of the electromagnetic wave shielding sheet.

A general electromagnetic wave shielding sheet requires high permeability for high charging efficiency, and accordingly, includes an appropriate magnetic material to implement high permeability. However, as the demand for rapid charging, high-capacity charging, wireless charging, etc., has increased, importance of a heat-radiation property for effectively removing heat that occurs during the charging is on the rise. However, when the magnetic material for implementing high permeability and inorganic particles for implementing excellent heat-radiation property are simply mixed to be formed into a single layer, it is difficult to simultaneously implement excellent charging efficiency and heat-radiation property. The reason is that an amount of the inorganic particles that is capable of being added to magnetic powder is limited, and when the inorganic particles have a relatively large amount, the heat-radiation property is increased, but permeability is decreased, and when the inorganic particles have a relatively small amount, even through it does not affect the charging efficiency, it is difficult to obtain thermal conductivity values required for the rapid charging, the high-capacity charging, etc.

That is, there is a trade-off between the charging efficiency and the heat-radiation property of the electromagnetic wave shielding sheet. Accordingly, in order to implement both of excellent charging efficiency and heat-radiation property, the electromagnetic wave shielding sheet according to an exemplary embodiment of the present invention is characterized by including a stack structure of a plurality of unit structures, each of the unit structures including a heat-radiating layer and a magnetic layer, wherein the sum of total thickness of the heat-radiating layers has a ratio of about 0.1 to about 0.7 with regard to the total thickness of the electromagnetic wave shielding sheet.

The stack structure includes a plurality of heat-radiating layers, and a plurality of magnetic layers, and means a structure in which the unit structures are stacked, that is, a structure in which the heat-radiating layers and the magnetic layers are alternately stacked with each other. Here, the sum of total thickness of the plurality of heat-radiating layers may have a ratio of about 0.1 to about 0.7 with regard to the total thickness of the electromagnetic wave shielding sheet, for example, a ratio of about 0.1 to about 0.6, for example, a ratio of a ratio of about 0.1 to about 0.5, for example, a ratio of about 0.2 to about 0.4, and for example, a ratio of about 0.2 to about 0.3.

When the ratio of total thickness of the heat-radiating layers with regard to total thickness of the electromagnetic wave shielding sheet is less than about 0.1, excellent heat-radiation property required for wireless charging, rapid charging, or high-capacity charging may not be implemented. When the ratio of total thickness of the heat-radiating layers with regard to total thickness of the electromagnetic wave shielding sheet is more than about 0.7, charging efficiency may be deteriorated.

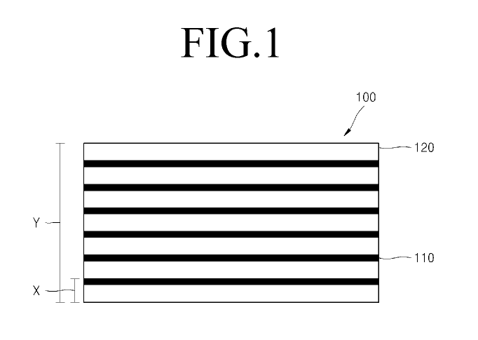

FIG. 1 schematically shows the electromagnetic wave shielding sheet 100 including a stack structure of a plurality of unit structures, each of the unit structures including a heat-radiating layer 110 and a magnetic layer 120 according to an exemplary embodiment of the present invention.

Referring to FIG. 1, the magnetic layer may be included as a top layer or a bottom layer of the stack structure. That is, one of the top layer or the bottom layer of the stack structure may be the magnetic layer or both of the top layer or the bottom layer of the stack structure may be the magnetic layers.

In the case where one of the top layer or the bottom layer of the stack structure is the magnetic layer, when the electromagnetic wave shielding sheet is mounted in an electronic device, a layer adjacent to other components, for example, a coil, etc., may be the magnetic layer, which may be advantageous for the electronic device mounted with the electromagnetic wave shielding sheet to implement excellent charging efficiency.

Referring to FIG. 1, the electromagnetic wave shielding sheet 100 is mounted in a portable terminal, etc., wherein both of the top layer and the bottom layer exposed to the outside may be the magnetic layers, and in this case, excellent charging efficiency and insulation property may be advantageously implemented by interaction with an adjacent power receiver, etc.

The electromagnetic wave shielding sheet may include the stack structure of a plurality of unit structures, thereby including a structure in which the heat-radiating layers and the magnetic layers are alternately stacked with each other, wherein the total thickness of the electromagnetic wave shielding sheet may be about 200 μm to about 500 μm, for example, about 300 μm to about 400 μm. The total thickness of the electromagnetic wave shielding sheet satisfies the above-described range, the electromagnetic wave shielding sheet may be appropriate to implement excellent heat-radiation property and excellent charging efficiency due to the stack structure, and may be appropriate to be mounted and applied to the inside of the electronic device.

Specifically, each of the heat-radiating layers may have a thickness of about 10 μm to about 60 μm, for example, about 10 μm to about 30 μm, for example, about 10 μm to about 20 μm, for example, about 40 μm to about 60 μm, and for example, about 40 μm to about 50 μm. The heat-radiating layer has the above-described range of thickness, such that the electromagnetic wave shielding sheet may have improved processability and excellent heat-radiation property.

Each of the magnetic layers may have a thickness of about 40 μm to about 100 μm, for example, about 40 μm to about 80 μm, and for example, about 40 μm to about 60 μm. The magnetic layer has the above-described range of thickness, such that the electromagnetic wave shielding sheet may simultaneously have excellent heat-radiation property and charging efficiency, and it may be preferred to secure appropriate processability and insulation property in the manufacturing process.

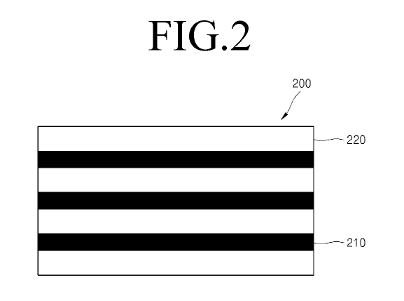

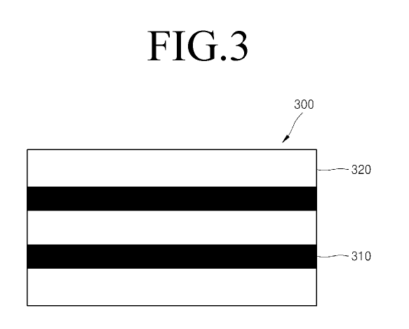

The stack structure may include about two to about four, for example, about two to about five, and for example, about two to about six unit structures. For example, as shown in FIG. 2, the stack structure may include three unit structures, and as shown in FIG. 3, the stack structure may include two unit structures. The number of unit structures may be appropriately controlled within a range in which the total thickness of the electromagnetic wave shielding sheet is about 200 μm to about 500 μm.

The electromagnetic wave shielding sheet includes the stack structure, and thus, includes a plurality of heat-radiating layers. The sum of total thickness of the heat-radiating layers may be about 20 μm to about 350 μm, for example, about 40 μm to about 200 μm, for example, about 40 μm to about 180 μm, and for example, about 40 μm to about 150 μm.

When the sum of total thickness of the heat-radiating layers is less than about 20 μm, it is difficult for the electromagnetic wave shielding sheet to implement excellent heat-radiation property. When the sum of total thickness of the heat-radiating layers is more than about 350 μm, permeability of the electromagnetic wave shielding sheet is excessively reduced, such that charging efficiency of the electronic device mounted with the electromagnetic wave shielding sheet is reduced.

For example, the stack structure includes about 5 heat-radiating layers each having a thickness of about 20 μm, such that the electromagnetic wave shielding sheet in which the sum of total thickness of the heat-radiating layers is about 100 μm may be implemented.

The heat-radiating layer is to implement excellent heat-radiation property of the electromagnetic wave shielding sheet on the basis of high thermal conductivity, and may include inorganic particles and an organic binder. The heat-radiating layer includes the inorganic particles and the organic binder, such that excellent durability of the electromagnetic wave shielding sheet may be secured while implementing excellent heat-radiation property.

Specifically, the heat-radiating layer may include about 80 wt % to about 99 wt % of the inorganic particles, and about 1 wt % to about 20 wt % of the organic binder. Specifically, the heat-radiating layer may include about 85 wt % to about 98 wt % of the inorganic particles, and about 2 wt % to about 15 wt % of the organic binder. More specifically, the heat-radiating layer may include about 90 wt % to about 95 wt % of the inorganic particles, and about 5 wt % to about 10 wt % of the organic binder.

When the content of the inorganic particle is less than about 80 wt %, and the content of the organic binder is more than about 20 wt %, it is difficult to expect a sufficient heat-radiation effect.

In addition, when the content of the inorganic particle is more than about 99 wt %, and the content of the organic binder is less than about 1 wt %, in the process for producing the electromagnetic wave shielding sheet, processability of the heat-radiating layer may be reduced, durability of the electromagnetic wave shielding sheet may be reduced, and the content of the organic binder holding the inorganic particles is insufficient as compared to the content of the inorganic particles, thereby resulting in loss of the inorganic particles on a surface of the heat-radiating layer.

The inorganic particle is to implement excellent heat-radiation property on the basis of high thermal conductivity. Specifically, the inorganic particle may include at least one selected from the group consisting of graphite, graphene, carbon nanotube (CNT), boron nitride (BN), aluminum nitride (AlN), and combinations thereof.

For example, the inorganic particle may be graphite particle, which is excellent, particularly in view of performance as compared to cost, and is advantageous to handle.

Further, for example, when the heat-radiating layer includes graphite as the inorganic particle, the graphite particle may have a diameter of about 5 μm to about 45 μm, which may be particularly advantageous for improving dispersabilitiy and coating property of a coating liquid in the process for producing the heat-radiating layer.

The organic binder serves to provide appropriate viscosity, secure durability of the electromagnetic wave shielding sheet, and hold and connect the inorganic particles in the process for producing the heat-radiating layer. Specifically, the organic binder may include at least one selected from the group consisting of a styrene-butadiene rubber (SBR), a styrene-ethylene-butylene-styrene copolymer (SEBS), an ethylene-vinyl acetate copolymer (EVA), low density polyethylene (LDPE), an acrylic resin, an ester-based resin, an epoxy resin, and combinations thereof.

For example, the organic binder may include the styrene-butadiene rubber (SBR), the styrene-ethylene-butylene-styrene copolymer (SEBS), and the acrylic resin, which is particularly advantageous for improving dispersibility and coating property of the inorganic particles.

The electromagnetic wave shielding sheet may include the magnetic layer to secure excellent charging efficiency of the electronic device mounted with the electromagnetic wave shielding sheet, and the magnetic layer may include magnetic materials and the organic binder.

The magnetic material may include at least one selected from the group consisting of iron, nickel, chromium, aluminum, and combinations thereof. Specifically, the magnetic layer may include iron, which is particularly advantageous for implementing high permeability.

The organic binder serves to excellently hold the magnetic materials, and specifically, may include at least one selected from the group consisting of a styrene-butadiene rubber (SBR), a styrene-ethylene-butylene-styrene copolymer (SEBS), an ethylene-vinyl acetate copolymer (EVA), low density polyethylene (LDPE), an acrylic resin, an ester-based resin, an epoxy resin, and combinations thereof.

For example, the magnetic layer may include the styrene-butadiene rubber (SBR), the styrene-ethylene-butylene-styrene copolymer (SEBS), and the acrylic resin, as the organic binders.

In the electromagnetic wave shielding sheet, the magnetic layer and the heat-radiating layer may include the same organic binder. Accordingly, at the time of thermocompressing in the process for producing the electromagnetic wave shielding sheet, bonding force between the magnetic layer and the heat-radiating layer may be increased, and as a result, durability of the electromagnetic wave shielding sheet may be improved.

Method for Producing Electromagnetic Wave Shielding Sheet

Another exemplary embodiment of the present invention is directed to providing a method for producing an electromagnetic wave shielding sheet including: preparing a magnetic layer; forming a unit structure by stacking a heat-radiating layer on one surface of the magnetic layer; forming a stack structure in which the magnetic layers and the heat-radiating layers are alternately stacked with each other by stacking the at least two unit structures; and forming the electromagnetic wave shielding sheet by thermocompressing the stack structure, wherein the sum of total thickness of the heat-radiating layers has a ratio of 0.1 to 0.7 with regard to the total thickness of the electromagnetic wave shielding sheet.

According to the method for producing an electromagnetic wave shielding sheet, the electromagnetic wave shielding sheet may be manufactured. In addition, in the method for producing an electromagnetic wave shielding sheet, details of the magnetic layer and the heat-radiating layer are the same as described above.

The preparing of the magnetic layer may be performed by positioning a magnetic layer on a plate, and then positioning a heat-radiating layer to be easily stacked on one surface of the magnetic layer.

The forming of the unit structure by stacking the heat-radiating layer on one surface of the magnetic layer may include: preparing a coating liquid by mixing an organic solvent; a solid containing inorganic particles, and an organic binder; and stacking the heat-radiating layer by coating the coating liquid on one surface of the magnetic layer.

Specifically, the coating liquid may include about 35 wt % to about 45 wt % of the organic solvent and about 55 wt % to about 65 wt % of the solid.

When the coating liquid includes less than about 35 wt % of the organic solvent and more than about 65 wt % of the solid, flowability of the coating liquid is deteriorated in the process for producing the electromagnetic wave shielding sheet, such that it is difficult to form the electromagnetic wave shielding sheet with a desired thickness, and a surface to be coated is not evenly formed, and accordingly, processability of the heat-radiating layer may be reduced.

In addition, when the coating liquid includes more than about 45 wt % of the organic solvent and less than about 55 wt % of the solid, dispersibility of the inorganic particles in the coating liquid is poor, such that the inorganic particles agglomerate together, and thus, it is difficult for the electromagnetic wave shielding sheet to implement excellent heat-radiation property required for rapid charging, high-capacity charging or wireless charging.

The solid includes the inorganic particles and the organic binder, and specifically has a paste form in which the inorganic particles are dispersed in the organic binder. Details of the inorganic particles and the organic binder are the same as described above.

That is, the solid may include about 80 wt % to about 99 wt % of the inorganic particles, and about 1 wt % to about 20 wt % of the organic binder. Specifically, the solid may include about 85 wt % to about 98 wt % of the inorganic particles, and about 2 wt % to about 15 wt % of the organic binder. More specifically, the solid may include about 90 wt % to about 95 wt % of the inorganic particles, and about 5 wt % to about 10 wt % of the organic binder.

When the content of the inorganic particle is less than about 80 wt %, and the content of the organic binder is more than about 20 wt %, it is difficult to expect a sufficient heat-radiation effect.

In addition, when the content of the inorganic particle is more than about 99 wt %, and the content of the organic binder is less than about 1 wt %, in the process for producing the electromagnetic wave shielding sheet, processability of the heat-radiating layer may be reduced, durability of the electromagnetic wave shielding sheet may be reduced, and the content of the organic binder holding the inorganic particles is insufficient as compared to the content of the inorganic particles, thereby resulting in loss of the inorganic particles on a surface of the heat-radiating layer.

The organic solvent may provide appropriate processability and coating property in the process for producing the heat-radiating layer, and may allow for the inorganic particles to be easily dispersed in the organic binder. Accordingly, the organic solvent may be variously selected depending on kinds and properties of the inorganic particles and the organic binder, and generally, may include at least one selected from the group consisting of methyl ethyl ketone (MEK), methyl isobutyl ketone (MIBK), ethanol, toluene, and combinations thereof.

For example, the heat-radiating layer may include ketones such as methyl ethyl ketone (MEK), etc., as the organic solvent, which is advantageous for a drying process since a boiling point is particularly low.

The preparing of the coating liquid by mixing the organic solvent and the solid is not specifically limited in view of a method, but for example, the organic solvent and the solid may be mixed by a paste mixer.

The coating of the coating liquid on one surface of the magnetic layer is not specifically limited in view of a method, but for example, may be performed by coating using a knife coater.

For example, as described above, when the coating liquid includes about 35 wt % to about 45 wt % of the organic solvent and about 55 wt % to about 65 wt % of the solid, excellent processability may be secured in the process for preparing the coating liquid and coating the coating liquid.

In the method for producing the electromagnetic wave shielding sheet, the forming of the stack structure in which the magnetic layers and the heat-radiating layers are alternately stacked with each other by stacking the at least two unit structures may include forming the magnetic layer as a top layer or a bottom layer of the stack structure.

For example, when the at least two unit structures are stacked, one unit structure may be positioned so that the magnetic layer is placed below, and then, the plurality of unit structures each having the same form as described above may be stacked, such that the magnetic layer may be included on the bottom of the stack structure.

Otherwise, the plurality of unit structures may be stacked in the same manner as in the above-described method, and finally, one magnetic layer may be further stacked on the heat-radiating layer of the lastly stacked unit structure, such that the magnetic layers may be included on both of the top and the bottom of the stack structure.

Here, for example, two, three, four, five or six unit structures may be stacked so that the magnetic layer is included on at least one of the top and the bottom.

The electromagnetic wave shielding sheet is mounted in a portable terminal, etc., and when the top layer or the bottom layer exposed to the outside is the magnetic layer, excellent charging efficiency and insulation property may be advantageously implemented by interaction with an adjacent power receiver, etc.

Specifically, the forming of the electromagnetic wave shielding sheet by thermocompressing the stack structure may be a step of thermocompressing the stack structure so that the sum of total thickness of the heat-radiating layers has a ratio of about 0.1 to about 0.7 with regard to the total thickness of the electromagnetic wave shielding sheet. For example, the ratio of the total thickness of the plurality of heat-radiating layers with regard to the total thickness of the electromagnetic wave shielding sheet may be about 0.1 to about 0.6, for example, about 0.1 to about 0.5, for example, about 0.2 to about 0.4, and for example, about 0.2 to about 0.3.

The ratio of the total thickness of the plurality of heat-radiating layers with regard to the total thickness of the electromagnetic wave shielding sheet satisfies the above-described range, such that excellent heat-radiation property according to high thermal conductivity may be implemented, while simultaneously maintaining high charging efficiency without significant deterioration of permeability.

In the forming of the electromagnetic wave shielding sheet by thermocompressing the stack structure, a thickness of the stack structure after the thermocompressing is thinner than a thickness of the stack structure before the thermocompressing. The total thickness range of the electromagnetic wave shielding sheet and the range of the sum of total thickness of the heat-radiating layers are the same as described above, and details of each thickness range of the heat-radiating layer and the magnetic layer are the same as described above.

That is, the total thickness of the final electromagnetic wave shielding sheet may be about 200 μm to about 500 μm, and each of the heat-radiating layers may have a thickness of about 10 μm to about 60 μm, and each of the magnetic layers may have a thickness of about 40 μm to about 100 μm.

In addition, in the final electromagnetic wave shielding sheet, the sum of total thickness of the heat-radiating layers may be about 20 μm to about 350 μm.

As described above, the thickness of the stack structure before the thermocompressing may be designed so that the heat-radiating layers, the magnetic layers, and the electromagnetic wave shielding sheet satisfy each thickness range as described above after the thermocompressing, and accordingly, in a process for forming the unit structures and the stack structure, excellent processability and coating property may be secured, and affinity at each interlayer interface may be increased to prevent delamination, such that high density after the thermocompressing may be achieved, and finally, heat-radiation property and charging efficiency may be maximized.

The forming of the electromagnetic wave shielding sheet by thermocompressing the stack structure may be performed by thermocompression at a temperature of about 140° C. to about 180° C. and under a pressure of about 40 kgf/cm² to about 120 kgf/cm². The temperature and the pressure at the time of thermocompressing satisfy the above-described range, such that the total thickness of the electromagnetic wave shielding sheet and the sum of total thickness of the heat-radiating layers may satisfy a ratio within the above-described range, and accordingly, excellent heat-radiation property and charging efficiency may be simultaneously implemented, and the heat-radiating layers and the magnetic layers may be strongly stacked without damaging components of each layer.

Hereinafter, Examples and Comparative Examples of the present invention are described. However, the following examples are only provided as one embodiment of the present invention, and the present invention is not limited to the following Examples.

### EXAMPLE AND COMPARATIVE EXAMPLE

TABLE 1

| | | | After thermocompressing | | |
|---|---|---|---|---|---|
| | | | | | Ratio of total |
| | | | | | thickness of |
| | Before thermocompressing | | | Total | heat-radiating |
| | Magnetic layer | Heat-radiating layer | Total | thickness of | layers with |
| | (thickness (μm) × | (thickness (μm) × | thickness | heat-radiating | regard to total |
| | the number of | the number of | of sheet | layer | thickness of |
| | layers) | layers) | (μm) | (μm) | sheet |
| Example 1 | 110 × 4 | 30 × 3 | 350 | 60 | 0.17 |
| Example 2 | 130 × 3 | 70 × 2 | 350 | 90 | 0.26 |
| Example 3 | 60 × 6 | 30 × 5 | 350 | 100 | 0.29 |
| Example 4 | 80 × 4 | 70 × 3 | 350 | 140 | 0.40 |
| Comparative | 520 × 1 | — | 350 | — | — |
| Example 1 | | | | | |
| Comparative | Simply mixing with 5 wt % of graphite | | 350 | — | — |
| Example 2 | | | | | |
| Comparative | 210 × 2 | 100 × 1 | 350 | 60 | 0.17 |
| Example 3 | | | | | |
| Comparative | 120 × 4 | 20 × 3 | 350 | 30 | 0.08 |
| Example 4 | | | | | |
| Comparative | 45 × 4 | 120 × 3 | 350 | 280 | 0.80 |
| Example 5 | | | | | |

### Example 1

One magnetic layer including ferrite and styrene-butadiene rubber (SBR) and having a thickness of 110 μm was prepared. Then, a solid including 95 wt % of graphite particles as inorganic particles and 5 wt % of styrene-butadiene rubber (SBR) as an organic binder was prepared. Next, a coating liquid that contains 60 wt % of the solid and 40 wt % of an organic solvent, the organic solvent containing methyl ethyl ketone (MEK) and toluene at a ratio of 1:1, was prepared by using a paste mixer (DAEWHA Tech Co., LTD, PDM-300). Then, the coating liquid was evenly dispersed through a roll mill process (EXAKT, 80E). Next, the coating liquid dispersed on the magnetic layer was coated and dried by using a knife coater (KIPAE, Comate™ 3000VH), thereby forming a unit structure in which one heat-radiating layer having a thickness of 30 μm is stacked on one surface of the magnetic layer. Three unit layers were stacked to form a stack structure in which the magnetic layers and the heat-radiating layers are alternately stacked with each other. Then, one magnetic layer having a thickness of 110 μm was further stacked on the top heat-radiating layer of the stack structure. Next, the stack structure was thermocompressed by using a hot press device (CARVER, 4PR1BOO), thereby manufacturing an electromagnetic wave shielding sheet having a total thickness of about 350 μm, wherein the sum of total thickness of the heat-radiating layers was about 60 μm.

### Example 2

An electromagnetic wave shielding sheet of Example 2 was conducted in the same manner as in Example 1 above except that two unit structures were stacked, each unit structure including one magnetic layer having a thickness of 130 μm and one heat-radiating layer having a thickness of 70 μm stacked on one surface of the magnetic layer, thereby forming a stack structure in which the magnetic layers and the heat-radiating layers are alternately stacked with each other, and then, one magnetic layer having a thickness of 130 μm was further stacked on the top heat-radiating layer of the stack structure, followed by thermocompressing, thereby manufacturing the electromagnetic wave shielding sheet having a total thickness of about 350 μm, wherein the sum of total thickness of the heat-radiating layers was about 90 μm.

### Example 3

An electromagnetic wave shielding sheet of Example 3 was conducted in the same manner as in Example 1 above except that five unit structures were stacked, each unit structure including one magnetic layer having a thickness of 60 μm and one heat-radiating layer having a thickness of 30 μm stacked on one surface of the magnetic layer, thereby forming a stack structure in which the magnetic layers and the heat-radiating layers are alternately stacked with each other, and then, one magnetic layer having a thickness of 60 μm was further stacked on the top heat-radiating layer of the stack structure, followed by thermocompressing, thereby manufacturing the electromagnetic wave shielding sheet having a total thickness of about 350 μm, wherein the sum of total thickness of the heat-radiating layers was about 100 μm.

### Example 4

An electromagnetic wave shielding sheet of Example 4 was conducted in the same manner as in Example 1 above except that three unit structures were stacked, each unit structure including one magnetic layer having a thickness of 80 μm and one heat-radiating layer having a thickness of 70 μm stacked on one surface of the magnetic layer, thereby forming a stack structure in which the magnetic layers and the heat-radiating layers are alternately stacked with each other, and then, one magnetic layer having a thickness of 80 μm was further stacked on the top heat-radiating layer of the stack structure, followed by thermocompressing, thereby manufacturing the electromagnetic wave shielding sheet having a total thickness of about 350 μm, wherein the sum of total thickness of the heat-radiating layers was about 140 μm.

### Comparative Example 1

A mixture including 92 wt % of ferrite and 8 wt % of styrene-butadiene rubber (SBR) was prepared. Then, an electromagnetic wave shielding sheet which is a single layer having the same thickness as that of the electromagnetic wave shielding sheet of Example 1 was manufactured by using the mixture.

### Comparative Example 2

A mixture including 92 wt % of ferrite, 5 wt % of graphite particles, and 3 wt % of styrene-butadiene rubber (SBR) as an organic binder was prepared. Then, an electromagnetic wave shielding sheet which is a single layer having the same thickness as that of the electromagnetic wave shielding sheet of Example 1 was manufactured by using the mixture.

### Comparative Example 3

One magnetic layer including ferrite and styrene-butadiene rubber (SBR) and having a thickness of 210 μm was prepared. Then, a solid including 95 wt % of graphite particles as inorganic particles and 5 wt % of styrene-butadiene rubber (SBR) as an organic binder was prepared. Next, a coating liquid that contains 60 wt % of the solid and 40 wt % of an organic solvent, the organic solvent containing methyl ethyl ketone (MEK) and toluene at a ratio of 1:1, was prepared by using a paste mixer (DAEWHA Tech Co., LTD, PDM-300). Then, the coating liquid was coated and dried onto magnetic layer by using a knife coater (KIPAE, Comate™ 3000VH), thereby forming a unit structure in which one heat-radiating layer having a thickness of 100 μm is stacked on one surface of the magnetic layer. Then, one magnetic layer having a thickness of 210 μm was further stacked on the top of the unit structure. Next, thermocompressing was performed by using a hot press device (CARVER, 4PR1BOO), thereby manufacturing an electromagnetic wave shielding sheet having a total thickness of about 350 μm, wherein the sum of total thickness of the heat-radiating layers was about 60 μm.

### Comparative Example 4

An electromagnetic wave shielding sheet of Comparative Example 4 was conducted in the same manner as in Example 1 above except that three unit structures were stacked, each unit structure including one magnetic layer having a thickness of 120 μm and one heat-radiating layer having a thickness of 20 μm stacked on one surface of the magnetic layer, thereby forming a stack structure in which the magnetic layers and the heat-radiating layers are alternately stacked with each other, and then, one magnetic layer having a thickness of 120 μm was further stacked on the top heat-radiating layer of the stack structure, followed by thermocompressing, thereby manufacturing the electromagnetic wave shielding sheet having a total thickness of about 350 μm, wherein the sum of total thickness of the heat-radiating layers was about 30 μm.

### Comparative Example 5

An electromagnetic wave shielding sheet of Comparative Example 5 was conducted in the same manner as in Example 1 above except that three unit structures were stacked, each unit structure including one magnetic layer having a thickness of 45 μm and one heat-radiating layer having a thickness of 120 μm stacked on one surface of the magnetic layer, thereby forming a stack structure in which the magnetic layers and the heat-radiating layers are alternately stacked with each other, and then, one magnetic layer having a thickness of 45 μm was further stacked on the top heat-radiating layer of the stack structure, followed by thermocompressing, thereby manufacturing the electromagnetic wave shielding sheet having a total thickness of about 350 μm, wherein the sum of total thickness of the heat-radiating layers was about 280 μm.

Evaluation

### Experimental Example 1

### Measurement of Thermal Diffusion Coefficient

With respect to the electromagnetic wave shielding sheets manufactured by Examples and Comparative Examples, thermal diffusion coefficient in an in-plane direction of each electromagnetic wave shielding sheet was measured by using a measuring device for thermal diffusion coefficient (NETZSCH, LFA447). Here, the in-plane direction refers to a plane direction parallel to a plane when the electromagnetic wave shielding sheet is placed on the plane.

### Experimental Example 2

### Measurement of Thermal Conductivity

With respect to the electromagnetic wave shielding sheets manufactured by Examples and Comparative Examples, thermal conductivity in an in-plane direction of each electromagnetic wave shielding sheet was measured by using a measuring device for thermal conductivity (NETZSCH, LFA447).

### Experimental Example 3

### Measurement of Permeability

With respect to the electromagnetic wave shielding sheets manufactured by Examples and Comparative Examples, permeability at 6 MHz was measured by using a measuring device for permeability (LE USA WALKER, AMH).

Experimental results obtained by the measurements of Experimental Examples 1 to 3 and the sum of total thickness of the heat-radiating layers of Examples 1 to 4 were shown in Table 2 below.

TABLE 2

| | Whether there is stack | Ratio of total thickness of | Thermal | | |
|---|---|---|---|---|---|
| | structure including at | heat-radiating layers with | diffusion | Thermal | |
| | least two unit | regard to total thickness of | coefficient | conductivity | Permeability |
| | structures | sheet | (mm²/s) | (W/mK) | (%) |
| Example 1 | ◯ | 0.17 | 4.14 | 9.05 | 38.70 |
| Example 2 | ◯ | 0.26 | 6.12 | 13.30 | 38.21 |
| Example 3 | ◯ | 0.29 | 6.26 | 13.71 | 35.81 |
| Example 4 | ◯ | 0.40 | 8.34 | 16.29 | 32.53 |
| Comparative | X | — | 1.14 | 2.51 | 46.00 |
| Example 1 | | | | | |
| Comparative | X | — | 2.26 | 4.75 | 39.00 |
| Example 2 | | | | | |
| Comparative | X | 0.17 | 2.28 | 5.02 | 38.07 |
| Example 3 | | | | | |
| Comparative | ◯ | 0.08 | 3.08 | 6.78 | 38.00 |
| Example 4 | | | | | |
| Comparative | ◯ | 0.80 | 12.57 | 26.40 | 25.05 |
| Example 5 | | | | | |

In order for the electromagnetic wave shielding sheet to simultaneously implement excellent charging efficiency and excellent heat-radiation property, the thermal diffusion coefficient needs to be about 4.00 mm²/s or more, and the thermal conductivity needs to be about 9.00 W/mK or more, and at the same time, the permeabilitiy needs to be about 30% or more.

As shown in Table 2 above, it could be confirmed that the electromagnetic wave shielding sheets of Examples 1 to 4 had the thermal diffusion coefficient of about 4.00 mm²or more, and the thermal conductivity of about 9.00 W/mK or more, thereby implementing excellent heat-radiation property, and at the same time, had the permeability of about 30% or more, thereby having excellent charging efficiency.

However, it could be appreciated that Comparative Example 1 had a structure of a single layer in which the inorganic particles are not included at all, and Comparative Example 2 had a structure of a single layer in which the inorganic particles are mixed with the magnetic material, wherein in both of Comparative Examples 1 and 2, the permeability was about 30% or more, which is high, but the thermal diffusion coefficient was less than about 4.00 mm²/s, and the thermal conductivity was less than about 9.00 W/mK, such that the heat-radiation property of Comparative Examples 1 and 2 was remarkably poorer than those of Examples 1 to 4. That is, it could be appreciated that the electromagnetic wave shielding sheets of Comparative Examples 1 and 2 could not have excellent heat-radiation property required for rapid charging, high-capacity charging or wireless charging, and accordingly, excellent charging efficiency and heat-radiation property could not be simultaneously implemented.

Further, it could be confirmed that in Comparative Example 3 without including the stack structure in which the at least two unit structures are stacked, the permeability was about 30% or more, which is high, but the thermal diffusion coefficient was less than about 4.00 mm²/s, and the thermal conductivity was less than about 9.00 W/mK, such that in consideration of specific thermal conductivity value, the heat-radiation property of Comparative Example 3 was better than those of Comparative Examples 1 and 2, but was remarkably poorer than those of Examples 1 to 4. Therefore, it could be confirmed that the electromagnetic wave shielding sheet of Comparative Example 3 could not simultaneously implement excellent charging efficiency and heat-radiation property.

Further, it could be appreciated that Comparative Example 4 included the stack structure in which the at least two unit structures are stacked, but a ratio of total thickness of the heat-radiating layers was less than 0.1 with regard to the total thickness of the electromagnetic wave shielding sheet, wherein the thermal diffusion coefficient was about 3.08 mm²/s, and the thermal conductivity was about 6.78 W/mK, such that the heat-radiation property of Comparative Example 4 was better than those of Comparative Examples 1 to 3, but was remarkably poorer than those of Examples 1 to 4.

In addition, it could be appreciated that Comparative Example 5 included the stack structure in which the at least two unit structures are stacked, but a ratio of total thickness of the heat-radiating layers was more than 0.7 with regard to the total thickness of the electromagnetic wave shielding sheet, wherein the thermal diffusion coefficient was about 12.57 mm²/s, and the thermal conductivity was about 26.40 W/mK, such that the heat-radiation property of Comparative Example 5 was excellent as compared to those of Examples 1 to 4, but the permeability of Comparative Example 5 was about 25.05%, which was poorer than those of Examples 1 to 4. That is, it could be confirmed that the electromagnetic wave shielding sheet of Example 5 could not simultaneously implement excellent heat-radiation property and excellent charging efficiency.

That is, it could be appreciated that the electromagnetic wave shielding sheet according to an exemplary embodiment of the present invention included the stack structure of a plurality of unit structures, each of the unit structures including the heat-radiating layer and the magnetic layer, and at the same time, the sum of total thickness of the heat-radiating layers had a ratio of 0.1 to 0.7 with regard to the total thickness of the electromagnetic wave shielding sheet, such that excellent heat-radiation property and the charging efficiency could be simultaneously implemented.

1. An electromagnetic wave shielding sheet comprising:
a stack structure of a plurality of unit structures, each of the unit structures comprising a heat-radiating layer and a magnetic layer,
wherein the sum of total thickness of the heat-radiating layers has a ratio of 0.1 to 0.7 with regard to the total thickness of the electromagnetic wave shielding sheet.

2. The electromagnetic wave shielding sheet of claim 1, wherein the stack structure includes the magnetic layer as a top layer or a bottom layer.

3. The electromagnetic wave shielding sheet of claim 1, wherein the total thickness of the electromagnetic wave shielding sheet is 200 μm to 500 μm.

4. The electromagnetic wave shielding sheet of claim 1, wherein the heat-radiating layer includes inorganic particles and an organic binder.

5. The electromagnetic wave shielding sheet of claim 4, wherein the heat-radiating layer includes 80 wt % to 99 wt % of the inorganic particles and 1 wt % to 20 wt % of the organic binder.

6. The electromagnetic wave shielding sheet of claim 4, wherein the inorganic particle includes at least one selected from the group consisting of graphite, graphene, carbon nanotube (CNT), boron nitride (BN), aluminum nitride (AlN), and combinations thereof.

7. The electromagnetic wave shielding sheet of claim 4, wherein the organic binder includes at least one selected from the group consisting of a styrene-butadiene rubber (SBR), a styrene-ethylene-butylene-styrene copolymer (SEBS), an ethylene-vinyl acetate copolymer (EVA), low density polyethylene (LDPE), an acrylic resin, an ester-based resin, an epoxy resin, and combinations thereof.

8. The electromagnetic wave shielding sheet of claim 1, wherein the magnetic layer and the heat-radiating layer include the same organic binder.

9. A method for producing an electromagnetic wave shielding sheet comprising:
preparing a magnetic layer;
forming a unit structure by stacking a heat-radiating layer on one surface of the magnetic layer;
forming a stack structure in which the magnetic layers and the heat-radiating layers are alternately stacked with each other by stacking the at least two unit structures; and
forming the electromagnetic wave shielding sheet by thermocompressing the stack structure,
wherein the sum of total thickness of the heat-radiating layers has a ratio of 0.1 to 0.7 with regard to the total thickness of the electromagnetic wave shielding sheet.

10. The method of claim 9, wherein the forming of the unit structure includes:
preparing a coating liquid by mixing an organic solvent with a solid containing inorganic particles and an organic binder and
stacking the heat-radiating layer by coating the coating liquid on one surface of the magnetic layer.

11. The method of claim 9, wherein the forming of the stack structure includes forming the magnetic layer as a top layer or a bottom layer of the stack structure.
